(19) United States
(12) Patent Application Publication
(10) Pub. No.: US 2025/0202434 A1
(43) Pub. Date: Jun. 19, 2025

(54) AMPLIFIER CIRCUIT

(71) Applicant: SUMITOMO ELECTRIC INDUSTRIES, LTD., Osaka (JP)

(72) Inventor: Hirotaka ASAMI, Osaka-shi (JP)

(73) Assignee: SUMITOMO ELECTRIC INDUSTRIES, LTD., Osaka (JP)

(21) Appl. No.: 18/958,483

(22) Filed: Nov. 25, 2024

(30) Foreign Application Priority Data
Dec. 14, 2023 (JP) 2023-211402

(51) Int. Cl. H03F 1/02; H03F 1/56; H03F 3/213

(52) U.S. Cl. CPC H03F 1/0288; H03F 1/56; H03F 3/213; H03F 2200/222; H03F 2200/387; H03F 2203/21142

(57) ABSTRACT

An amplifier circuit includes a first divider, a control amplifier, a second divider, a first auxiliary amplifier, a second auxiliary amplifier, a first node to which a sixth signal is input, a second node to which a seventh signal is input, a third node to which a third signal is input, and a fourth node to which an output signal is output, and includes a lumped constant branch line coupler that combines the sixth signal, the seventh signal, and the third signal and outputs the combined signal as an output signal, and a signal of a center frequency input to the first node has a power amplitude that is smaller than the power amplitude of the signal distributed to the third node, and the power amplitude of the sixth signal is greater than the power amplitude of the seventh signal.

### CROSS REFERENCE TO RELATED APPLICATIONS

This application claims priority based on Japanese Patent Application No. 2023-211402 filed on Dec. 14, 2023, and the entire contents of the Japanese patent applications are incorporated herein by reference.

### FIELD

A certain aspect of the embodiments is related to an amplifier circuit.

### BACKGROUND

An LMBA (Load Modulated Balanced Amplifier) includes a control amplifier for amplifying one of the signals into which an input signal is divided, and a balance amplifier for amplifying the other signal to which the input signal is divided. It is known to use a 3 dB branch line coupler as a combiner for combining an output signal of the control amplifier and an output signal of the balance amplifier (for example, Patent Document 1: U.S. Patent Application Publication No. 2022/0255506).

### SUMMARY

A amplifier circuit according to the present disclosure includes: a first divider configured to divide an input signal into a first signal and a second signal; a control amplifier configured to amplify the first signal and output the first signal after amplifying as a third signal; a second divider configured to divide the second signal into a fourth signal and a fifth signal of which phases at a center frequency of an operation band are different from each other; a first auxiliary amplifier configured to amplify the fourth signal and output the fourth signal after amplifying as a sixth signal; a second auxiliary amplifier configured to amplify the fifth signal and output the fifth signal after amplifying as a seventh signal; and a lumped element branch line coupler that includes a first node to which the sixth signal is input, a second node to which the seventh signal is input, a third node to which the third signal is input, and a fourth node configured to output an output signal, the lumped element branch line coupler combining the sixth signal, the seventh signal and the third signal and outputting a combined signal of the sixth signal, the seventh signal and the third signal as the output signal, an amplitude of an electrical power of a signal where a signal of the center frequency which is input to the first node is distributed to the third node being smaller than an amplitude of a signal where the signal of the center frequency which is input to the first node is distributed to the fourth node, and wherein an amplitude of an electrical power of the sixth signal is larger than that of the seventh signal.

### BRIEF DESCRIPTION OF DRAWINGS

FIG. 1 is a circuit diagram of an amplifier circuit according to a first embodiment.

FIG. 2 is a circuit diagram illustrating Example 1 of a combiner in a first embodiment.

FIG. 3 is a circuit diagram illustrating Example 2 of a combiner in a first embodiment.

FIG. 4 is a circuit diagram of an amplifier circuit in Comparative Example 1.

FIG. 5 is a circuit diagram illustrating a part of an amplifier circuit in Comparative Example 2.

FIG. 6 is a circuit diagram illustrating a part of an amplifier circuit in Comparative Example 2.

FIG. 7 is an example in which a distributed constant type branch line coupler is used in a combiner.

FIG. 8 is a schematic diagram explaining an operation of a combiners in Comparative Example 3 and a first embodiment.

FIG. 9 is a circuit diagram illustrating a balance amplifier in Comparative Example 3.

FIG. 10 is a circuit diagram illustrating a balance amplifier in Example 1 of a first embodiment.

FIG. 11 is a circuit diagram illustrating a balance amplifier in Example 2 of a first embodiment.

FIG. 12 is a plan view illustrating a first implementation example of a combiner and amplifier in a first embodiment.

FIG. 13 is a plan view illustrating a second implementation example of a combiner and amplifier in a first embodiment.

FIG. 14 is a plan view illustrating a third implementation example of a combiner and amplifier in a first embodiment.

### DETAILED DESCRIPTION OF EMBODIMENTS

In LMBA, from the viewpoint of coupler characteristics, a quarter-wavelength line is used as the 3 dB branch-line coupler. If a distributed constant type branch-line coupler is used, the amplifier circuit becomes larger. If a lumped constant type branch-line coupler is used as the 3 dB branch-line coupler, loss becomes large and characteristics deteriorate.

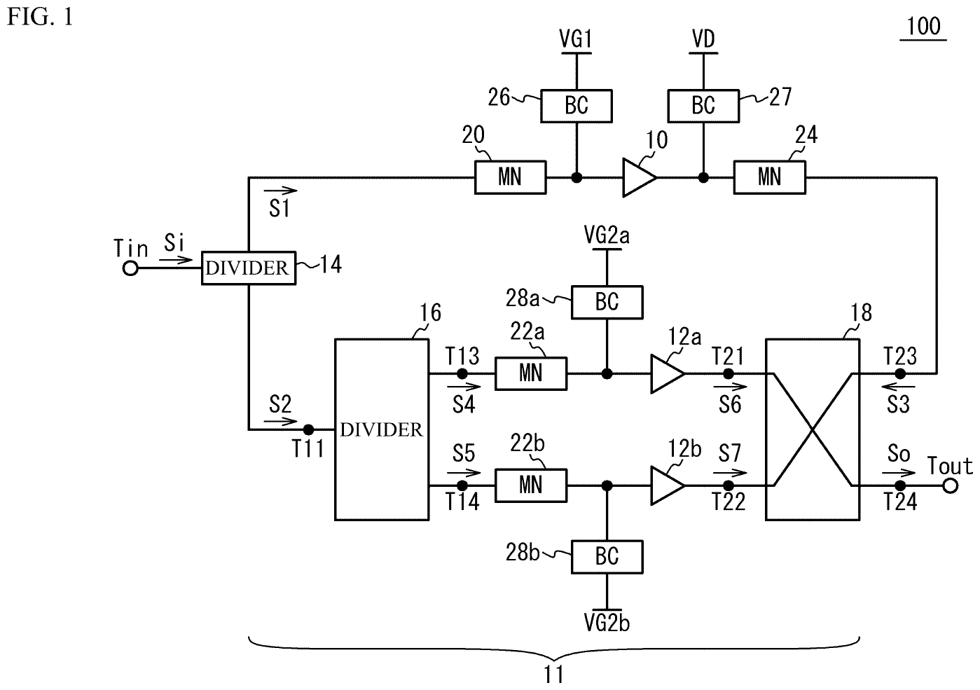

The present disclosure has been made in view of the above problems, and an object of the present disclosure is to suppress deterioration of characteristics.

[First Embodiment] FIG. 1 is a circuit diagram of an amplifier circuit according to a first embodiment. As illustrated in FIG. 1, in an amplifier circuit 100 of the first embodiment, a control amplifier 10 and a balance amplifier 11 are connected in parallel between an input terminal Tin and an output terminal Tout. A high-frequency signal is input to the input terminal Tin as an input signal Si. When the amplifier circuit 100 is used in a mobile communication base station, the frequency of the high-frequency signal is, for example, 0.5 GHz or more and 10 GHz or less. A divider 14 (first divider) divides the input signal Si input to the input terminal Tin into signals S1 (first signal) and S2 (second signal).

The signal S1 passes through a matching circuit (MN: Matching Network) 20 and is input to the control amplifier 10. The matching circuit 20 matches the impedance in a case of seeing the matching circuit 20 from the divider 14 with the impedance in a case of seeing the control amplifier 10 from the matching circuit 20. A bias circuit (BC) 26 that supplies an input bias voltage VG1 to the control amplifier 10 is connected to a node in a line between the divider 14 and the control amplifier 10. The bias circuit 26 supplies the input bias voltage VG1 to the control amplifier 10 and suppresses the signal S1 from leaking to the power supply that supplies the input bias voltage VG1.

The control amplifier 10 amplifies the signal S1 and outputs the amplified signal as a signal S3 (third signal). The signal S3 amplified by the control amplifier 10 passes through a matching circuit 24 and is input to a terminal T23 of a combiner 18. The matching circuit 24 matches the impedance in a case of seeing the matching circuit 24 from the control amplifier 10 with the impedance in a case of seeing the combiner 18 from the matching circuit 24. A bias circuit 27 that supplies an output bias voltage VD to the control amplifier 10 is connected to a node in a line between the control amplifier 10 and the combiner 18. The bias circuit 27 supplies the output bias voltage VD to the control amplifier 10 and suppresses the signal S3 from leaking to the power supply that supplies the output bias voltage VD.

The signal S2 divider by the divider 14 is input to the balance amplifier 11. The balance amplifier 11 includes a divider 16, auxiliary amplifiers 12a and 12b, and the combiner 18. The divider 16 (second divider) divides the signal S2 input to the terminal T11 into signals S4 (fourth signal) and S5 (fifth signal), which are output from terminals T13 and T14, respectively. The signal S5 is delayed in phase from the signal S4 by, for example, about 90°. The amplitudes of the signals S5 and S4 are, for example, approximately the same. The 90° does not have to be exactly 90°, and may be, for example, greater than 85° and less than 95°, or greater than 88° and less than 92°. The same is true for the combiner 18.

The divider 16 may be a distributed constant branch line coupler using a distributed constant line, a lumped constant branch line coupler using an inductor and a capacitor, a divider using a Wilkinson type divider and a λ/4 transmission line, a distributed coupling coupler in which two transmission lines are electromagnetically coupled, or a tightly wound coil coupler in which two inductors are electromagnetically coupled.

The signal S4 passes through a matching circuit 22a and is input to the auxiliary amplifier 12a. The matching circuit 22a matches the impedance in a case of seeing the matching circuit 22a from the divider 16 with the impedance in a case of seeing the auxiliary amplifier 12a from the matching circuit 22a. A bias circuit 28a that supplies an input bias voltage VG2a to the auxiliary amplifier 12a is connected to a node in a line between the divider 16 and the auxiliary amplifier 12a. The bias circuit 28a supplies the input bias voltage VG2a to the auxiliary amplifier 12a and suppresses the signal S4 from leaking to the power supply that supplies the input bias voltage VG2a. The auxiliary amplifier 12a (first auxiliary amplifier) amplifies the signal S4 and outputs the amplified signal as a signal S6 (sixth signal). The signal S6 amplified by the auxiliary amplifier 12a is input to the terminal T21 of the combiner 18.

The signal S5 passes through a matching circuit 22b and is input to the auxiliary amplifier 12b. The matching circuit 22b matches the impedance in a case of seeing the matching circuit 22b from the divider 16 with the matching circuit 22b in a case of seeing the auxiliary amplifier 12b from the matching circuit 22b. A bias circuit 28b that supplies an input bias voltage VG2b to the auxiliary amplifier 12b is connected to a node in a line between the divider 16 and the auxiliary amplifier 12b. The bias circuit 28b supplies the input bias voltage VG2b to the auxiliary amplifier 12b, and suppresses the signal S5 from leaking to the power supply that supplies the input bias voltage VG2b. The auxiliary amplifier 12b (second auxiliary amplifier) amplifies the signal S5 and outputs the amplified signal as a signal S7 (seventh signal). The signal S7 amplified by the auxiliary amplifier 12b is input to the terminal T22 of the combiner 18.

A matching circuit for matching impedance may be connected between the auxiliary amplifiers 12a and 12b and the combiner 18. In the first embodiment, the signal of the control amplifier 10 adjusts the load of the auxiliary amplifiers 12a and 12b. For this reason, a matching circuit may not be necessarily provided between the auxiliary amplifiers 12a and 12b and the combiner 18. A harmonic processing circuit for reflecting harmonic signals in the signals S6 and S7 may be connected between the auxiliary amplifiers 12a and 12b and the combiner 18. The harmonic signals are, for example, double or triple waves when the operating frequency of the amplifier circuit is the fundamental wave. A bias circuit for supplying an output bias voltage to the auxiliary amplifiers 12a and 12b may be provided between the auxiliary amplifiers 12a and 12b and the combiner 18. In the first embodiment, the output bias voltage of the auxiliary amplifiers 12a and 12b is supplied to the auxiliary amplifiers 12a and 12b from the bias circuit 27 through the combiner 18.

The combiner 18 is a lumped constant branch line coupler. Terminals T21 to T24 are terminals of the branch line coupler, with the terminals T21 and T24 located diagonally and the terminals T22 and T23 located diagonally. A signal S6 is input to the terminal T21. A signal S7 is input to the terminal T22. A signal S3 is input to the terminal T23. An output signal So is output from the terminal T24. The combiner 18 combines the signals S3, S6, and S7, and outputs the combined signal as the output signal So.

The control amplifier 10 and the auxiliary amplifiers 12a and 12b are transistors such as FETs (Field Effect Transistors), with their sources grounded, high-frequency signals input to their gates, and high-frequency signals output from their drains. The FETs are, for example, GaN HEMTs (Gallium Nitride High Electron Mobility Transistors) or LDMOSs (Laterally Diffused Metal Oxide Semiconductors). The control amplifier 10 and the auxiliary amplifiers 12a and 12b may each be provided with multi-stage FETs. When the control amplifier 10 and the auxiliary amplifiers 12a and 12b are FETs, the input bias voltages VG1, VG2a and VG2b are gate bias voltages, and the output bias voltage VD is a drain bias voltage.

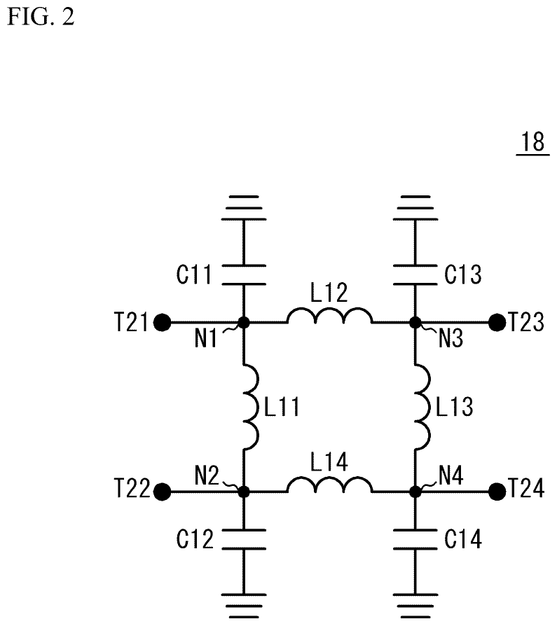

FIG. 2 is a circuit diagram illustrating Example 1 of the combiner of the first embodiment. As illustrated in FIG. 2, the combiner 18 is a lumped constant type branch line coupler. Nodes N1 (first node), N2 (second node), N3 (third node) and N4 (fourth node) are electrically connected to the terminals T21, T22, T23 and T24, respectively. The first end of the inductor L11 (first inductor) is electrically connected to the node N1, and the second end is electrically connected to the node N2. The first end of the inductor L12 (second inductor) is electrically connected to the node N1, and the second end is electrically connected to the node N3. The first end of the inductor L13 (third inductor) is electrically connected to the node N3, and the second end is electrically connected to the node N4. The first end of the inductor L14 (fourth inductor) is electrically connected to the node N2, and the second end is electrically connected to the node N4. The capacitors C11 (first capacitor), C12 (second capacitor), C13 (third capacitor) and C14 (fourth capacitor) are shunt-connected to the nodes N1, N2, N3 and N4, respectively. Each of the capacitors C11 to C14 may be configured with a plurality of capacitors connected in shunt.

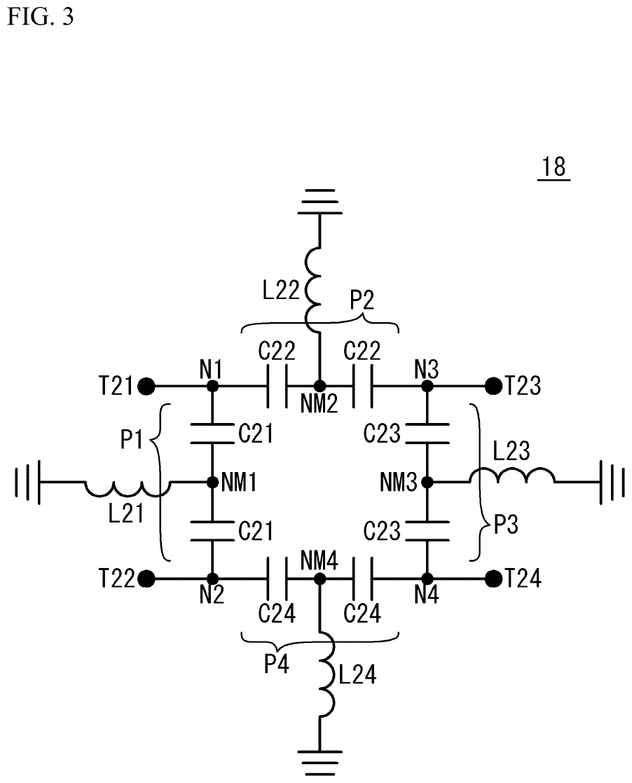

FIG. 3 is a circuit diagram illustrating Example 2 of the combiner iof the first embodiment. As illustrated in FIG. 3, in the combiner 18, a pair of capacitors C21 (first capacitors) are connected in series to a path P1 (first path) connecting the nodes N1 and N2. An inductor L21 (first inductor) is shunt-connected to a node NM1 (first intermediate node) between the capacitors C21 in the path P1. A pair of capacitors C22 (second capacitors) are connected in series to a path P2 (second path) connecting the nodes N1 and N3. An inductor L22 (second inductor) is shunt-connected to a node NM2 (second intermediate node) between the capacitors C22 in the path P2. A pair of capacitors C23 (third capacitors) are connected in series to a path P3 (third path) connecting the nodes N3 and N4. An inductor L23 (third inductor) is shunt-connected to a node NM3 (third intermediate node) between the capacitors C23 in the path P3. A pair of capacitors C24 (fourth capacitors) are connected in series to a path P4 (fourth path) connecting the nodes N2 and N4. An inductor L24 (fourth inductor) is shunt-connected to a node NM4 (fourth intermediate node) between the capacitors C24 in the path P4.

The matching circuits 20, 22a, 22b, and 24 are passive circuits including inductors and capacitors, and are, for example, inductors connected in series, π-type circuits with a CLC configuration, T-type circuits with an LCL configuration, L-type circuits with an LC configuration, or combinations of these circuits.

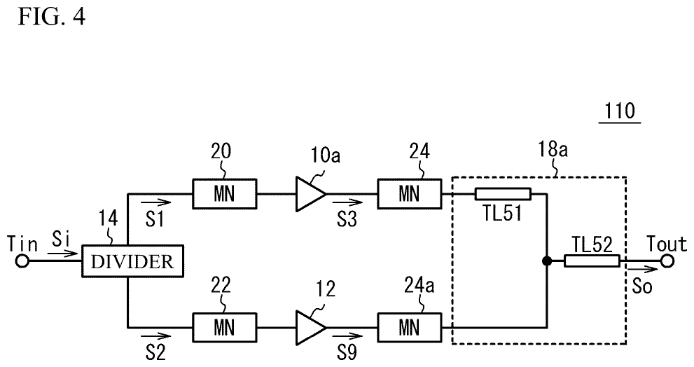

The control amplifier 10 corresponds to a main amplifier of a Doherty amplifier circuit, and the auxiliary amplifiers 12a and 12b correspond to peak amplifiers of the Doherty amplifier circuit. The control amplifier 10 operates in class AB or class B, and the auxiliary amplifiers 12a and 12b operate in class C. When the input power of the input signal Si is small, the control amplifier 10 mainly amplifies the input signal Si. When the input power increases, in addition to the control amplifier 10, the auxiliary amplifiers 12a and 12b amplify the peak of the input signal Si. As a result, the control amplifier 10 and the auxiliary amplifiers 12a and 12b amplify the input signal Si.

[Comparative Example 1] As Comparative Example 1, a Doherty amplifier circuit will be described. FIG. 4 is a circuit diagram of an amplifier circuit according to Comparative Example 1. As illustrated in FIG. 4, in an amplifier circuit 110 of Comparative Example 1, a main amplifier 10a and a peak amplifier 12 are provided in parallel between the input terminal Tin and the output terminal Tout. The divider 14 divides the input signal Si into the signals S1 and S2. The main amplifier 10a amplifies the signal S1 that has passed through the matching circuit 20, and outputs the amplified signal as the signal S3 to a combiner 18a via the matching circuit 24. The peak amplifier 12 amplifies the signal S2 that has passed through a matching circuit 22, and outputs the amplified signal as a signal S9 to the combiner 18a via a matching circuit 24a.

The combiner 18a is equipped with λ/4 transmission lines TL51 and TL52 as impedance converters. The impedance in a case of seeing the combiner 18a from the matching circuit 24 and the load impedance of the peak amplifier 12 are modulated using the λ/4 transmission lines TL51 and TL52.

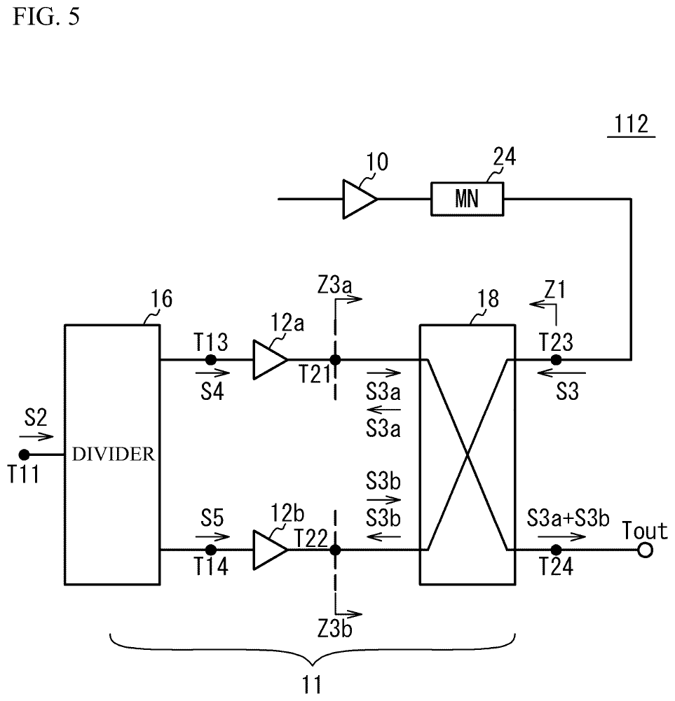

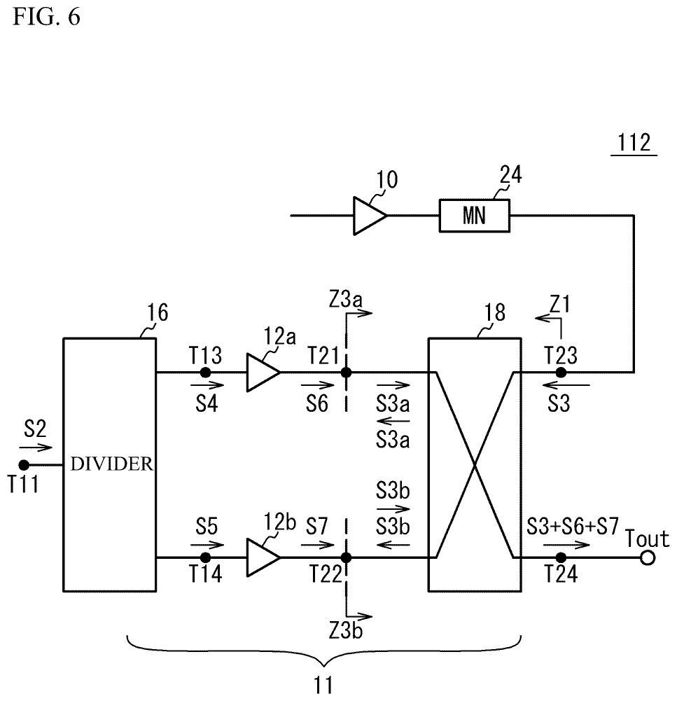

In Comparative Example 1, when the frequency changes, the electrical length of the λ/4 transmission line deviates from λ/4, making it difficult to widen the operating band. In one example, the bandwidth ratio of the combiner using the λ/4 transmission lines TL51 and TL52 is about 8%. In the LMBA of the first embodiment, a branch line coupler is used to modulate the load impedance of the auxiliary amplifiers 12a and 12b, making it possible to widen the operating band. The bandwidth ratio of the branch line coupler is, for example, up to 120% in a commercially available hybrid coupler. In this way, the LMBA can widen the bandwidth of the combiner 18.

[Comparative Example 2] As Comparative Example 2, an LMBA in which the combining ratio of the combiner 18 is 1:1 will be described. FIG. 5 and FIG. 6 are circuit diagrams illustrating a part of an amplifier circuit 112 in Comparative Example 2. FIG. 5 and FIG. 6 illustrate the circuits following the control amplifier 10 and the balance amplifier 11. In Comparative Example 2, the power combining ratio at which the combiner 18 combines signals S6 and S7 in FIG. 6 is 1:1.

Using FIG. 5, when the electrical power of the input signal Si is low and the auxiliary amplifiers 12a and 12b are not operating, the signal S3 input to the combiner 18 from the terminal T23 is divides into two signals S3a and S3b at the terminals T21 and T22. The electrical power amplitude ratio of the signals S3a and S3b is 1:1. The phase of the signal S3b at the terminal T22 delays behind the phase of the signal S3a at the terminal T21 by 90°. Signals S3a and S3b are reflected at the terminals T21 and T22, respectively. The reflected signals S3a and S3b are combined at the terminal T24. The phase of the signal S3a reflected at the terminal T21 delays behind the phase of the signal S3b reflected at the terminal T22 by 90°. As a result, the phases of the signals S3a and S3b are aligned at the terminal T24, and the signal S3 is combined. The combined signal S3 is output as the output signal So to the output terminal Tout.

At this time, the reflection coefficient (for example, the absolute value of the impedances Z3a and Z3b) in a case of seeing the combiner 18 from the auxiliary amplifiers 12a and 12b is approximately 1. The impedances Z3a and Z3b that serve as loads for the auxiliary amplifiers 12a and 12b are substantially high. On the other hand, the impedance Z1 in a case of seeing the terminal T23 from the matching circuit 24 is the reference impedance (for example, 5052) that is the input impedance of the terminal T23.

Next, using FIG. 6, when the electrical power of the input signal Si is large and the auxiliary amplifiers 12a and 12b are operating, the signal S7 is 90° behind the signal S6 in phase. The signal S3b at the terminal T22 is 90° behind the signal S3a at the terminal T21 in phase. As a result, by appropriately adjusting the phase difference between the signals S1 and S2, the phase of the signals S6 and S3a at the terminal T21 is optimized (for example, the phases of the signals S6 and S3a are aligned), and the phase of the signals S7 and S3b at the terminal T22 is optimized (for example, the phases of the signals S7 and S3b are aligned). The signal S6+S3a combined at the terminal T21 and the signal S7+S3b combined at the terminal T22 are combined at the terminal T24. The combined signal S3+S6+S7 is output to the output terminal Tout as the output signal So.

At this time, the signals incident on the terminals T21 and T22 from the auxiliary amplifiers 12a and 12b are substantially S6+S3a and S7+S3b, respectively, and the signals reflected at the terminals T21 and T22 are substantially S3a and S3b, respectively. Therefore, the reflection coefficient (for example, the absolute value of the impedances Z3a and Z3b) in a case of seeing the terminals T21 and T22 from the auxiliary amplifiers 12a and 12b is smaller than 1, and becomes smaller as the amplitude of the electrical power of the signals S6 and S7 increases. The impedances Z3a and Z3b that serve as the loads on the auxiliary amplifiers 12a and 12b become substantially lower as the amplitude of the electrical power of the signals S6 and S7 increases. In this way, the combiner 18 modulates the impedances Z3a and Z3b that serve as the loads on the combiner 18 seen from the auxiliary amplifiers 12a and 12b depending on the amplitude of the signals S6 and S7. On the other hand, the impedance Z1 in a case of seeing the terminal T23 from the matching circuit 24 is a reference impedance (for example, 50 (2) regardless of the amplitude of the signals S6 and S7.

When the electrical power of the output signal So is the maximum value in the operating range of the amplifier circuit, the output power of the output signal So is the saturated power Psat. At the saturated power Psat, the output power of the main amplifier 10a and the peak amplifier 12 in Comparative Example 1, and the output power of the control amplifier 10 and the auxiliary amplifiers 12a and 12b in Comparative Example 2 are saturated. Note that the output power being saturated here includes a state in which the output power is lower by 1 dB or less or 2 dB or less than the complete saturation state. When the electrical power of the output signal So is the minimum value in the operating range of the amplifier circuit, the back-off power Pbo is taken. At the back-off power Pbo, the main amplifier 10a in Comparative Example 1 is beginning to saturate, and the output power of the control amplifier 10 in Comparative Example 2 is saturated.

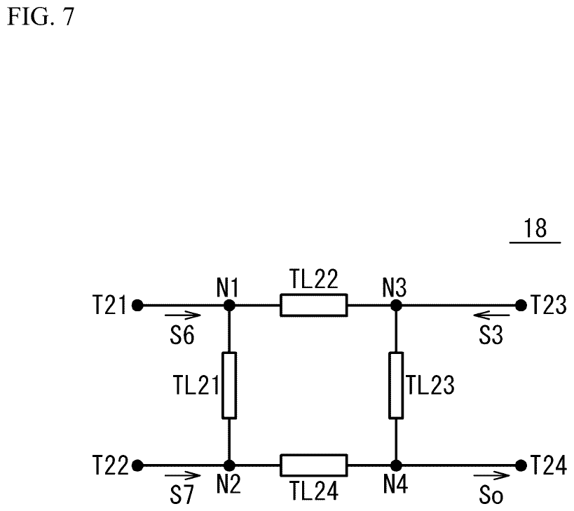

FIG. 7 illustrates an example in which a distributed constant type branch line coupler is used in a combiner. As illustrated in FIG. 7, transmission lines TL21, TL22, TL23, and TL24 are connected between the nodes N1 and N2, between the nodes N1 and N3, between the nodes N3 and N4, and between the nodes N2 and N4, respectively. The transmission lines TL21 to TL24 are 24 transmission lines. The electrical length of the λ/4 transmission line is, for example, approximately N/4. Here, A is the wavelength of the center frequency fo of the operating band of the amplifier circuit 100. The terminal T21 and the node N1, the terminal T22 and the node N2, the terminal T23 and the node N3, and the terminal T24 and the node N4 are connected by transmission lines. The signal S6 input to the terminal T21, the signal S7 input to the terminal T22, and the signal S3 input to the terminal T23 are combined, and the combined signal is output from the terminal T24 as the output signal So.

Distributed constant branch-line couplers are large because they use λ/4 lines. Therefore, a lumped constant branch-line coupler as illustrated in FIG. 2 and FIG. 3 is used as the combiner 18. When the combiner 18 combines the power of signals S6 and S7 at a combining ratio of 1:1, the inductance of inductors L11 to L14 becomes large. Inductors L11 to L14 with large inductance have large losses. This causes the characteristics of the LMBA to deteriorate. [Comparative Example 3] As Comparative Example 3, an LMBA in which the combiner 18 does not have a combining ratio of 1:1 will be described. Instead of the combining ratio of the combiner 18, the distribution ratio at which the electrical power of the signal S6 input to terminal T21 is distributed to terminals T24 and T23 is used as an index. The signal output to the terminal T23 is the signal S6a, and the signal output to the terminal T24 is the signal S6b. The electrical power amplitudes of the signals S6, S6a, and S6b are A6, A6a, and A6b, respectively. The ratio of the amplitude A6a to the amplitude A6b is A6a:A6b, which is expressed in dB, A6a-A6b [dB]. The characteristic impedance of the transmission lines TL21 and TL23 in FIG. 7 is Zc1, and the characteristic impedance of the transmission lines TL22 and TL24 is Zc2.

Table 1 shows the characteristic impedances Zc1, Zc2 and V2×Zc2/Zc1 for achieving the ratio A6a-A6b [dB].

TABLE 1

| A6a-A6b [dB] | −5 | −3 | −2 | 0 | 2 | 3 | 5 |
|---|---|---|---|---|---|---|---|
| Zc1 [Ω] | 28.10 | 35.40 | 39.70 | 50 | 63.00 | 70.60 | 89.00 |
| Zc2 [Ω] | 24.49 | 28.89 | 31.09 | 35.35 | 39.16 | 40.80 | 43.59 |
| \sqrt{2} · Zc2/Zc1 | 1.233 | 1.154 | 1.108 | 1.000 | 0.879 | 0.817 | 0.693 |

In Table 1, the reference impedance Zo is set to 50Ω. The reference impedance Zo corresponds to the impedance in a case of seeing the terminals T21, T22, T23 and T24 from the outside, and in particular corresponds to the impedance in a case of seeing the terminal T24 from the outside.

We will explain how to determine the values of the capacitors C11 to C14 and the inductors L11 to L14 when the lumped constant branch-line coupler of FIG. 2 is used instead of the distributed constant branch-line coupler of FIG. 7. The capacitance of the capacitors C11 to C14 is set to C1, the inductance of the inductors L11 and L13 to L1 (first inductance), and the inductance of the inductors L12 and L14 to L2 (second inductance). The center frequency of the operating band is fo. In this case, the capacitance C1 and the inductances L1 and L2 are determined by the following formulas.

$$C 1 = 1 / ( 2 π fo \times Zc 1 ) + 1 / ( 2 π fo \times Zc 2 ) \qquad ( Formula 1 )$$

$$L 1 = Zc 1 / ( 2 π fo ) \qquad ( Formula 2 )$$

$$L 2 = Zc 2 / ( 2 π fo ) \qquad ( Formula 3 )$$

We will now explain how to determine the values of capacitors C21 to C24 and inductors L21 to L24 when using the lumped constant branch-line coupler of FIG. 3 instead of the distributed constant branch-line coupler of FIG. 7. The capacitance of the capacitors C21 and C23 is set as C1 (first capacitance), the capacitance of the capacitors C22 and C24 as C2 (second capacitance), the inductance of the inductors L11 and L13 as L1 (first inductance), and the inductance of the inductors L12 and L14 as L2 (second inductance). The center frequency of the operating band is set as fo. In this case, the capacitances C1 and C2 and the inductances L1 and L2 are determined by the following formulas.

$$C 1 = 1 / ( 2 π fo \times Zc 1 ) \qquad ( Formula 4 )$$

$$C 2 = 1 / ( 2 π fo \times Zc 2 ) \qquad ( Formula 5 )$$

$$L 1 = Zc 1 / ( 2 π fo ) \qquad ( Formula 6 )$$

$$L 2 = Zc 2 / ( 2 π fo ) \qquad ( Formula 7 )$$

As shown in Table 1, when the amplitudes A6a and A6b are equal, in other words, when the signal S6 is equally divided into S6a and S6b, the characteristic impedance Zc1 is the reference impedance Zo, which is 50Ω, and the characteristic impedance Zc2 is Zo/√2, which is 35.35Ω.

When A6a-A6b is made smaller than when A6a-A6b=0 dB, the characteristic impedance Zc1 is made smaller than the reference impedance Zo, and the characteristic impedance Zc2 is made larger than Zc1/√2. In this case, the characteristic impedances Zc1 and Zc2 are both smaller than Zc1 and Zc2 when A6a−A6b=0 dB. This reduces the inductances L1 and L2, and the losses in the inductors L11 to L14 and L21 to L24 can be suppressed.

When A6a-A6b is made larger than when A6a-A6b=0 dB, the characteristic impedance Zc1 is made larger than the reference impedance Zo, and the characteristic impedance Zc2 is made smaller than Zc1/√2. In this case, the characteristic impedances Zc1 and Zc2 are both larger than Zc1 and Zc2 when A6a−A6b=0 dB. Therefore, the inductances L1 and L2 are increased, and the losses in the inductors L11 to L14 and L21 to L24 increase.

From the viewpoint of improving the high frequency characteristics of the combiner 18, the characteristic impedance Zc1 is made smaller than the reference impedance Zo, and the characteristic impedance Zc2 is made smaller than Zc1/√2. The characteristic impedance Zc1 may be set to 0.99 times or less, 0.90 times or less, 0.8 times or less, or 0.7 times or less of the reference impedance Zo. The characteristic impedance Zc2 may be set to 1.01 times or more, 1.1 times or more, 1.15 times or more, or 1.2 times or more of Zc1/√2. From the viewpoint of not making A6a-A6b too small, the characteristic impedance Zc1 may be set to 0.1 times or more of the reference impedance Zo, and the characteristic impedance Zc2 may be set to 10 times or less of Zc1/√2.

As a result of the above, the inductances L1 and L2 become smaller than the inductance when A6a−A6b=0 dB, and the capacitance C1 becomes larger than the capacitance when A6a−A6b=0 dB.

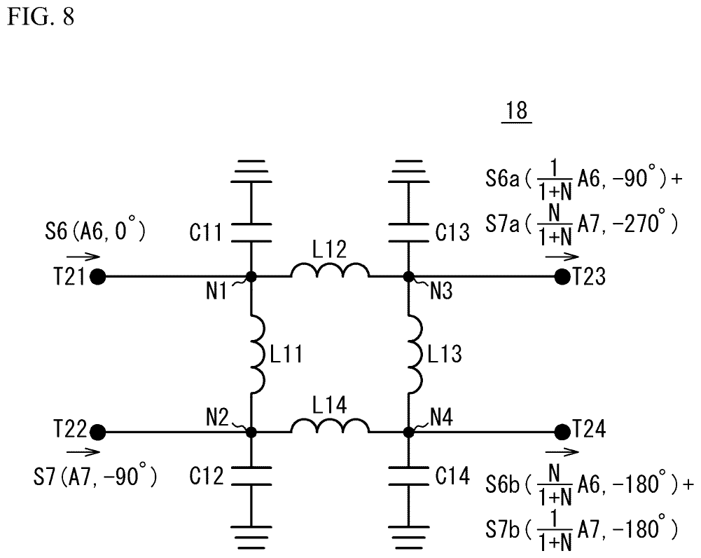

FIG. 8 is a schematic diagram explaining the operation of the combiner in Comparative Example 3 and the first embodiment. The impedance in a case of seeing the terminal T24 from the outside is the reference impedance Zo (for example, 50 (2), which corresponds to the characteristic impedance of the transmission line connecting the node N4 and the terminal T24. The inductance L1 of the inductors L11 and L13, the inductance L2 of the inductors L12 and L14, and the capacitance C1 of the capacitors C11 to C14 are set to values calculated from the characteristic impedances Zc1 and Zc2 in Table 1.

The amplitude of the signal S6 input to the terminal T21 is A6 and the phase is 0°. The amplitude of the signal S7 input to the terminal T22 is A7 and the phase is −90°. The signals S6 and S7 are represented as (A6, 0°) and (A7, −90°), respectively. The signal S6 is divided and the signals output to the terminals T23 and T24 are the signals S6a and S6b, respectively. The ratio A6b:A6a of the amplitudes of the signals S6b and S6a in W notation is N:1 (N>1). In this case, the signals S6a and S6b are ((1/(1+N))×A6, −90°) and ((N/(1+N))×A6, −180°), respectively. The signals S7a and S7b are ((N/(1+N))×A7, −270°) and ((1/(1+N))×A7, −180°), respectively.

At the terminal T24, the signals S6b and S7b are in phase, and the signal S6b with amplitude (N/(1+N))×A6 and the signal S7b with amplitude (1/(1+N))×A7 are combined.

At the terminal T23, the signals S6a and S7a are in opposite phase. When N=1, the amplitudes of the signals S6a and S7a are (½)×A6 and (½)×A7, respectively, and since the amplitudes of A6 and A7 are almost the same, the signals S6a and S7a are compensated. As a result, no signal is output from the terminal T23. As a result, the impedance Z1 in a case of seeing the terminal T23 from the matching circuit 24 is constant regardless of the amplitudes of the signals S6 and S7, and is the reference impedance Zo.

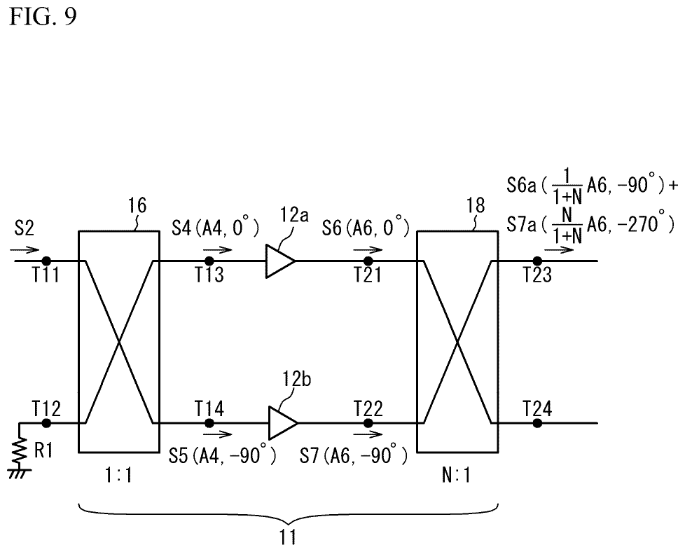

The case where N>1 will be described using Comparative Example 3. FIG. 9 is a circuit diagram illustrating a balance amplifier in Comparative Example 3. As illustrated in FIG. 9, in Comparative Example 3, as described in FIG. 6, the ratio A6b:A6a of the amplitudes of the signals S6b and S6a in the combiner 18 is N:1 (N>1). The divider 16 is a branch line coupler, in which the signal S2 is input to the terminal T11, and the signals S4 and S5 are output from the terminals T13 and T14. The terminal T12 is grounded via a reference resistor R1 (for example, 50Ω). The ratio of the amplitude of the signal S5 to the amplitude of the signal S4 in the divider 16 is 1:1. Therefore, the signal S4 output to the terminal T13 is (A4, 0°). The signal S5 output from the terminal T14 is (A4, −90°). The amplitudes of the signals S4 and S5 are approximately the same, A4. The physical sizes of the auxiliary amplifiers 12a and 12b are the same, and their saturation powers are also the same. The input bias voltages supplied to the auxiliary amplifiers 12a and 12b are the same, and their output bias voltages are also the same. As a result, the amplitudes of the signals S6 and S7 are approximately the same, A6. Therefore, the signal S6 input to the terminal T21 is (A6, 0°), and the signal S7 input to the terminal T22 is (A6, −90°).

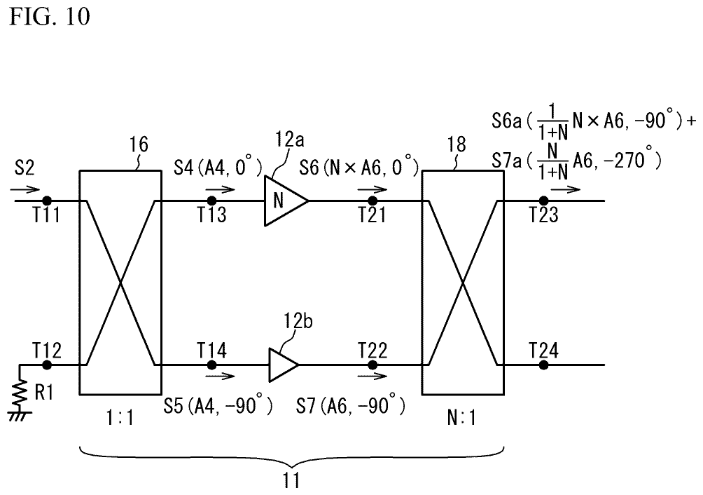

The signal S6a output from the terminal T23 is ((1/(1+N))× A6, 90°), and the signal S7a is ((N/(1+N))× A6, −270°). Because the signals S6a and Sa are in opposite phase, the signal S6a+S7a becomes ((1−N)/(1+N)× A6, −90°), and when N>1, the signals S6a and S7a are not compensated for. For this reason, when the magnitudes of the signals S6 and S7 change, the impedance Z1 which acts as a load on the control amplifier 10 changes. For example, when the output electrical power Pout is the back-off electrical power Pbo, the impedance Z1 is the reference impedance Zo. When the output electrical power Pout is the saturation power Psat, the impedance Z1 changes from the reference impedance Zo due to the influence of the signal S6a+S7a output from the terminal T23 of the combiner 18.

[Example 1 of the first embodiment] FIG. 10 is a circuit diagram illustrating a balance amplifier in Example 1 of the first embodiment. As illustrated in FIG. 10, the signal distribution ratio of the divider 16 is 1:1. The physical size of the auxiliary amplifier 12a is about N times the physical size of the auxiliary amplifier 12b. For example, when the auxiliary amplifiers 12a and 12b are FETs, the gate width of the auxiliary amplifier 12a is about N times the gate width of the auxiliary amplifier 12b. The saturation electrical power of the auxiliary amplifier 12a is about N times the saturation electrical power of the auxiliary amplifier 12b.

The amplitudes of the signals S4 and S5 divided by the divider 16 are approximately the same, A4. When both the auxiliary amplifiers 12a and 12b are used at saturation electrical power, the amplitude A6 of the signal S6 is N times the amplitude A7 of the signal S7. Therefore, the signal S6 input to the terminal T21 is (N×A6, 0°), and the signal S7 input to the terminal T22 is (A6, −90°).

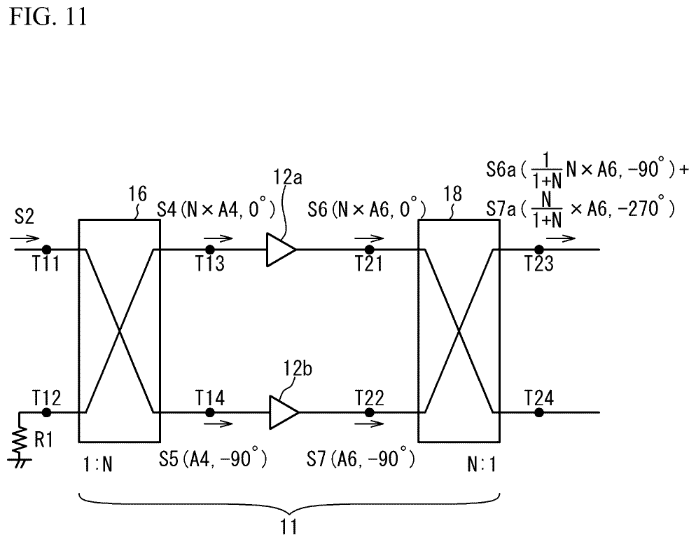

The signal S6a output from the terminal T23 is ((1/(1+N))×N×A6, −90°), and the signal S7a is ((N/(1+N))×A6, −270°). The amplitudes of the signals Sa and S7a are both (N/(1+N)×A6), and since the signals S6a and S7a are in opposite phase, the amplitude of the signal S6a+S7a is almost 0. Thus, when the output power Pout is the back-off electrical power Pbo and when the output electrical power Psat is the saturation electrical power Psat, the impedance Z1 is the reference impedance Zo.

[Example 2 of the first embodiment] FIG. 11 is a circuit diagram illustrating a balance amplifier in Example 2 of the first embodiment. As illustrated in FIG. 11, the signal distribution ratio of the divider 16 is 1:N. The physical sizes of the auxiliary amplifiers 12a and 12b are almost the same. The saturation electrical powers of the auxiliary amplifiers 12a and 12b are almost the same. When the divider 16 is a branch line coupler, the distribution ratio of the divider 16 is set to 1:N by setting the characteristic impedances Zc1 and Zc2 as shown in Table 1. When another coupler is used for the divider 16, the distribution ratio can be changed using a known method.

The amplitude of the signal S4 divided by the divider 16 is about N times the amplitude of the signal S5. Therefore, the signal S4 is (N×A4, 0°) and the signal S5 is (A4, −90°). If the auxiliary amplifiers 12a and 12b do not reach the saturation electrical power and have almost the same power gain, the amplitude of the signal S6 is N times the amplitude of the signal S7. Therefore, signal S6 is (N×A6, 0°) and signal S7 is (A6, −90°).

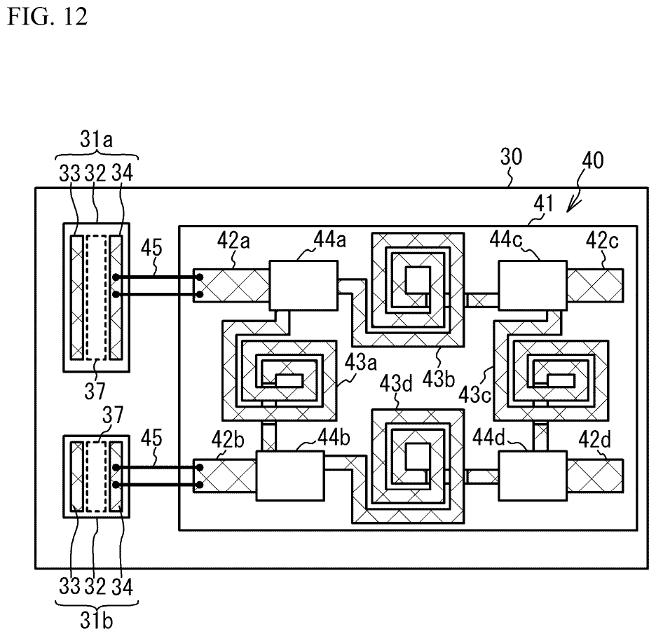

Therefore, as in Example 1, the signal S6a output from the terminal T23 is ((1/(1+N))×N×A6, −90°), and the signal S7a is ((N/(1+N))×A6, −270°). The amplitude of signal S6a+S7a is almost 0. Therefore, even if the magnitude of signals S6 and S7 changes, the change in impedance Z1 is suppressed.

[Implementation Example 1 of Combiner and Amplifier] FIG. 12 is a plan view illustrating Implementation Example 1 of the combiner and the amplifier in Example 1. As illustrated in FIG. 12, semiconductor chips 31a and 31b and a passive element chip 40 are mounted on a substrate 30. The top surface of the substrate 30 is, for example, a conductive layer, and a reference potential such as ground potential is supplied to the conductive layer. The semiconductor chips 31a and 31b each include a transistor 37 corresponding to the auxiliary amplifiers 12a and 12b, a substrate 32, and pads 33 and 34 provided on the substrate 32. The pad 33 is an input pad for receiving a high-frequency signal, such as a gate pad. The pad 34 is an output pad for receiving a high-frequency signal, such as a drain pad. When the transistor 37 is a GaN HEMT, the substrate 32 is, for example, a silicon carbide substrate, a sapphire substrate, or a gallium nitride substrate. The pads 33 and 34 are, for example, a gold layer, a copper layer, or an aluminum layer.

The passive element chip 40 is, for example, an IPD (Integrated Passive Device) formed using MMIC (Monolithic Microwave Integrated Circuit) technology. On a substrate 41 of the passive element chip 40, there are provided lines 42a to 42d, spiral inductors 43a to 43d, and MIM (Metal Insulator Metal) capacitors 44a to 44d. The lines 42a to 42d are formed by a metal layer provided on the passive element chip 40. The MIM capacitors 44a to 44d are formed by laminating a metal layer, a dielectric layer, and a metal layer provided on the passive element chip 40. The substrate 41 is, for example, a silicon substrate or a gallium arsenide substrate. The metal layer on the substrate 41 is, for example, a gold layer, a copper layer, or an aluminum layer. The dielectric layer of the MIM capacitors 44a to 44d is, for example, a silicon nitride layer or a silicon oxide layer.

The lines 42a to 42d form a microstrip line together with the substrate 30. The microstrip lines formed by the lines 42a to 42d correspond to the transmission lines between the terminals T21 to T24 and the nodes N1 to N4 in FIG. 2, respectively. The characteristic impedance of the transmission lines formed by the lines 42a to 42d is the reference impedance. In particular, the line 42d is connected to the load via the output terminal Tout, and the characteristic impedance of the transmission line formed by the line 42d is the reference impedance. The spiral inductors 43a to 43d correspond to the inductors L11 to L14 in FIG. 2, respectively. The MIM capacitors 44a to 44d correspond to the capacitors C11 to C14 in FIG. 2, respectively. The pads 34 of the semiconductor chips 31a and 31b and the lines 42a and 42b are electrically connected by bonding wires 45.

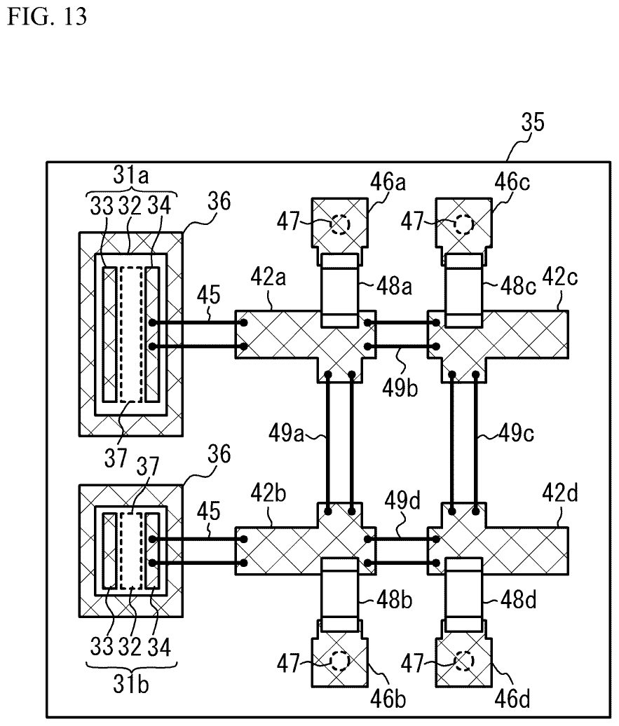

As in Example 1 of the first embodiment in FIG. 10, the size of the transistors (for example, the gate width of the FET) of the semiconductor chip 31a is larger than that of the semiconductor chip 31b. The inductances of the spiral inductors 43a to 43d and the capacitances of the MIM capacitors 44a to 44d are values calculated from the characteristic impedances Zc1 and Zc2 in Table 1.

[Implementation Example 2 of combiner and amplifier] FIG. 13 is a plan view illustrating Implementation Example 2 of combiner and amplifier in the first embodiment. Referring to FIG. 13, a conductive layer to which a reference potential such as a ground potential is supplied is provided on the bottom surface of a substrate 35. The substrate 35 is a dielectric substrate. On the substrate 35, a ground pattern 36, the lines 42a to 42d, and patterns 46a to 46d are provided using a metal layer. The semiconductor chips 31a and 31b are mounted on the ground pattern 36. Chip capacitors 48a to 48d are provided between the lines 42a to 42d and the patterns 46a to 46d, respectively. The pads 34 of the semiconductor chips 31a and 31b and the lines 42a and 42b are electrically connected by the bonding wires 45. The lines 42a and 42b, the lines 42a and 42c, the lines 42c and 42d, and the lines 42b and 42d are electrically connected by bonding wires 49a to 49d, respectively. The patterns 46a to 46d are electrically connected to a conductor layer on the bottom surface of the substrate 35 to which a reference potential is supplied through a via 47. The substrate 35 is, for example, a glass epoxy substrate or a ceramic substrate. The metal layer on the substrate 35 is, for example, a gold layer, a copper layer, or an aluminum layer. The other configuration is the same as Implementation Example of the combiner and amplifier in FIG. 12.

The lines 42a to 42d form a microstrip line. The microstrip lines formed by the lines 42a to 42d correspond to the transmission lines between the terminals T21 to T24 and the nodes N1 to N4 in FIG. 2, respectively. The characteristic impedance of the transmission line formed by the lines 42a to 42d is the reference impedance. The bonding wires 49a to 49d correspond to the inductors L11 to L14 in FIG. 2, respectively.

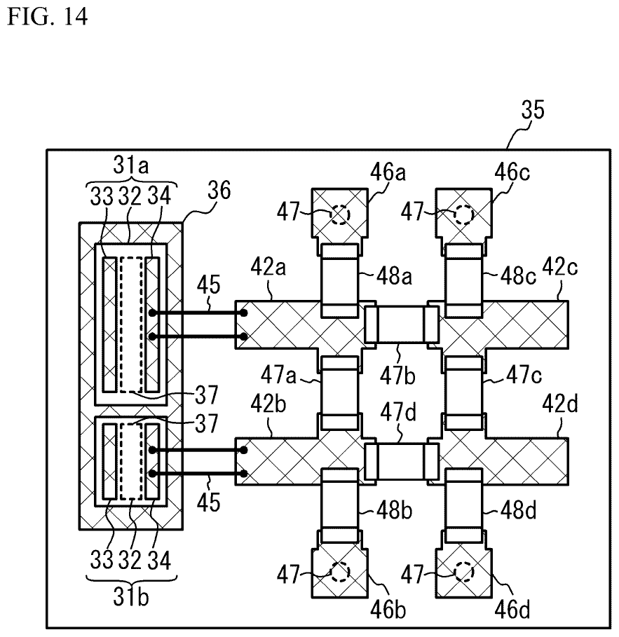

The chip capacitors 48a to 48d correspond to the capacitors C11 to C14 in FIG. 2, respectively. The inductances of the bonding wires 49a to 49d and the capacitances of the chip capacitors 48a to 48d are values calculated from the characteristic impedances Zel and Zc2 in Table 1.

[Implementation Example 3 of the combiner and amplifier] FIG. 14 is a plan view illustrating Implementation Example 3 of the combiner and amplifier in the first embodiment. As illustrated in FIG. 14, chip inductors 47a to 47d are provided in place of the bonding wires 49a to 49d, respectively. The other configurations are the same as Implementation Example 2 of the combiner and amplifier in FIG. 13, and a description thereof will be omitted.

In The first embodiment, when the lumped-constant branch-line coupler of FIG. 2 is used as the combiner 18, from Table 1, if Zc1<Zo (Equation 8) and Zc2>Zc1/√2 (Equation 9), the inductance of inductors L11 to L14 can be reduced and the loss of inductors L11 to L14 can be reduced. From Equations 2, 3, 8, and 9, L1<Zo/2πfo (Equation 10) and L2>L1/√2 (Equation 11), Equations 8 and 9 can be satisfied.

This allows the inductance of inductors L11 to L14 to be reduced. Therefore, the insertion loss of the inductors L11 to L14 can be suppressed, and deterioration of characteristics can be suppressed.

From the viewpoint of reducing inductance L1, the following relationships of L1<0.9×Zo/2πfo, L1<0.8×Zo/2πfo, or L1<0.7×Zo/2πfo may be satisfied. From the viewpoint of functioning as a branch line coupler, the following relationships of L2>1.1×L1/√2, L2>1.15×L1/√2, or L2>1.2×L1/√2 may be satisfied. From the viewpoint of reducing inductance L1, the relationship of L2<Zo/2πfo may be satisfied.

As shown in Table 1, the relationship of Zc2<Zc1 (Equation 12) is satisfied. Therefore, from formulas 1, 8, and 12, the relationship of C>1/(2πfo×Zo)+1/(2πfo×Zo)=1/(πfo×Zo) (formula 13) is satisfied. This allows the combiner 18 to function as a branch-line coupler.

From the viewpoint of functioning as a branch-line coupler, the following relationships of C>1.1/(fo×Zo), C>1.2/(πfo×Zo), and C>1.3/(πfo×Zo). Also, C<5/(πfo×Zo) may be satisfied.

When the lumped-constant branch-line coupler of FIG. 3 is used as the combiner 18, the inductance values of the inductors L21 to L24 that satisfy formulas 8 and 9 are the same as formulas 10 and 11, from formulas 6 and 7. This makes it possible to suppress the insertion loss of the inductors L21 to L24, and to suppress deterioration of characteristics.

From the viewpoint of reducing inductance L1, the following relationships of L1<0.9×Zo/2πfo, L1<0.8×Zo/2πfo, or L1<0.7×Zo/2πfo may be satisfied. From the viewpoint of functioning as a branch line coupler, the following relationships of L2>1.1×L1/√2, L2>1.15×L1/√2, or L2>1.2×L1/√2 may be satisfied. From the viewpoint of reducing inductance L1, the relationship of L2<Zo/2πfo may be satisfied.

The capacitance values of the capacitors C21 to C24 are C1>1/(2πfo×Zo) (Formula 14) from formulas 4 and 8, and C2>1/(2πfo×Zo) (Formula 15) and C2<√2/(2πfo×Zo) (Formula 16) from formulas 5, 9 and 12. This allows the combiner 18 to function as a branch line coupler.

From the viewpoint of functioning as a branch line coupler, the following relationships of C1>1.1/(2πfo×Zo), C1>1.2/(2πfo×Zo), C1>1.3/(2πfo×Zo) or C1<5/(2πfo×Zo) may be satisfied. The following relationships of C2>1.05/(2πfo×Zo), C2>1.1/(2πfo×Zo), C2<0.9×12/(2πfo×Zo), C2<0.85×12/(2πfo×Zo), or C2<0.8×√2/(2πfo×Zo) may be satisfied.

In this way, when the combiner 18 is a lumped constant type branch line coupler, the amplitude of the electrical power of the signal S6 input to the node N1 distributed to the node N3 is smaller than the amplitude of the electrical power of the signal distributed to the node N4. This makes it possible to reduce the inductance of the inductors L11 to L14 and L21 to L24. Therefore, it is possible to suppress the insertion loss of the inductors L11 to L14 and L21 to L24, and to suppress the deterioration of the characteristics. However, as in Comparative Example 3, the impedance Z1 in a case of seeing the combiner 18 from the control amplifier 10 changes due to changes in the signals S6 and S7. Therefore, the electrical power amplitude of the signal S6 is made larger than the electrical power amplitude of the signal S7. This makes it possible to reduce the signal S6a+S7a output from the terminal T23 as in Examples 1 and 2 of the first embodiment. Therefore, it is possible to suppress the fluctuation of the impedance Z1 due to changes in the signals S6 and S7, and to suppress deterioration of the characteristics.

The first ratio of the electrical power amplitude A6 of the signal S6 to the electrical power amplitude A7 of the signal S7 is A6/A7. The second ratio of the electrical power amplitude A6b of the signal S6b distributed to the terminal T24 to the electrical power amplitude A6a of the signal S6a distributed to the terminal T23 of the signal S6 with the center frequency fo input to the terminal T21 is A6b/A6a. When the first ratio A6/A7 and the second ratio A6b/A6a are expressed in dB, as in Example 1 and Example 2 of the first embodiment, when the first ratio and the second ratio are both N, the difference between the first ratio A6/A7 and the second ratio A6b/A6a is 0 dB. At this time, the signal S6a+S7a output from the terminal T23 is approximately 0. From the viewpoint of suppressing the change in the impedance Z1 due to the magnitude of the signals S6 and S7, the difference between the first ratio A6/A7 and the second ratio A6b/A6a may be 1 dB or less, 0.5 dB or less, or 0.3 dB or less. The difference between A6/A7 and A6b/A6a corresponds to |A6/A7-A6b/A6al.

From the viewpoint of miniaturizing the combiner 18, the second ratio A6b/A6a may be set to 2 dB or more, 3 dB or more, or 4 dB or more. If the second ratio A6b/A6a is too large, the signal output from the terminal T24 may deteriorate. From this viewpoint, the second ratio A6b/A6a may be set to 10 dB or less.

As in Example 1 of the first embodiment, from the viewpoint of increasing the first ratio A6/A7, the saturation electrical power of the auxiliary amplifier 12a is greater than the saturation electrical power of the auxiliary amplifier 12b. The saturation electrical power of the auxiliary amplifier 12a relative to the saturation electrical power of the auxiliary amplifier 12b may be set to 1 dB or more, 2 dB or more, or 3 dB or more. From the viewpoint of not increasing the first ratio A6/A7 too much, the saturation electrical power of the auxiliary amplifier 12a relative to the saturation electrical power of the auxiliary amplifier 12b may be set to 10 dB or less.

In order to make the saturation electrical power of the auxiliary amplifier 12a larger than that of the auxiliary amplifier 12b, the physical size of the auxiliary amplifier 12a is larger than that of the auxiliary amplifier 12b. For example, when the auxiliary amplifiers 12a and 12b are FETs, the gate width of the auxiliary amplifier 12a may be larger than that of the auxiliary amplifier 12b, and may be 1.3 times or more, 1.6 times or more, or 2 times or more than that of the auxiliary amplifier 12b. In addition, the gate width of the auxiliary amplifier 12a may be 10 times or less than that of the auxiliary amplifier 12b.

As in Example 2 of the first embodiment, from the viewpoint of increasing the first ratio A6/A7, the amplitude A4 of the electrical power of the signal S4 is larger than the amplitude A5 of the electrical power of the signal S5. The ratio of the amplitude A4 of the electrical power of the signal S4 to the amplitude A5 of the electrical power of the signal S5 may be 1 dB or more, 2 dB or more, or 3 dB or more. In order not to make the first ratio A6/A7 too large, the ratio of the amplitude A5 to the amplitude A4 may be set to 10 dB or less.

In addition to Examples 1 and 2 of the first embodiment, there is another method of making the first ratio A6/A7 greater than 1, for example, a method of combining Examples 1 and 2. That is, the saturation electrical power of the auxiliary amplifier 12a may be made greater than the saturation electrical power of the auxiliary amplifier 12b, and the amplitude A4 of the electrical power of the signal S4 may be made greater than the amplitude A5 of the electrical power of the signal S5. In addition, the first ratio A6/A7 may be made greater than 1 by appropriately setting the bias voltages of the auxiliary amplifiers 12a and 12b.

The reference impedance is the characteristic impedance of the transmission line (the transmission line provided between the node N4 and the output terminal Tout) formed by the line 42d in FIG. 12 to FIG. 14. This is because a load of the reference impedance is connected to the output terminal Tout.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. An amplifier circuit comprising:
a first divider configured to divide an input signal into a first signal and a second signal;
a control amplifier configured to amplify the first signal and output the first signal after amplifying as a third signal;
a second divider configured to divide the second signal into a fourth signal and a fifth signal of which phases at a center frequency of an operation band are different from each other;
a first auxiliary amplifier configured to amplify the fourth signal and output the fourth signal after amplifying as a sixth signal;
a second auxiliary amplifier configured to amplify the fifth signal and output the fifth signal after amplifying as a seventh signal; and
a lumped element branch line coupler that includes a first node to which the sixth signal is input, a second node to which the seventh signal is input, a third node to which the third signal is input, and a fourth node configured to output an output signal, the lumped element branch line coupler combining the sixth signal, the seventh signal and the third signal and outputting a combined signal of the sixth signal, the seventh signal and the third signal as the output signal, an amplitude of an electrical power of a signal where a signal of the center frequency which is input to the first node is distributed to the third node being smaller than an amplitude of a signal where the signal of the center frequency which is input to the first node is distributed to the fourth node,
wherein an amplitude of an electrical power of the sixth signal is larger than that of the seventh signal.

2. The amplifier circuit as claimed in claim 1,
wherein the lumped element branch line coupler comprises:
a first inductor of which a first terminal is connected to the first node and of which a second terminal is connected to the second node;
a second inductor of which a first terminal is connected to the first node and of which a second terminal is connected to the third node;
a third inductor of which a first terminal is connected to the third node and of which a second terminal is connected to the fourth node; and
a fourth inductor of which a first terminal is connected to the second node and of which a second terminal is connected to the fourth node, and
wherein when the center frequency is fo, a reference impedance is Zo, a first inductance of the first inductor and the third inductor is L1, and a second inductance of the second inductor and the fourth inductor is L2, relationships of L1<Zo/2πfo and L2>L1/√2 are satisfied.

3. The amplifier circuit as claimed in claim 2,
wherein the lumped element branch line coupler comprises:
a first capacitor which is shunt-connected to the first node;
a second capacitor which is shunt-connected to the second node;
a third capacitor which is shunt-connected to the third node; and
a fourth capacitor which is shunt-connected to the fourth node, and
wherein a capacitance of the first capacitor, the second capacitor, the third capacitor and the fourth capacitor is C, a relationship of C>1/(πfo×Zo) is satisfied.

4. The amplifier circuit as claimed in claim 1,
wherein the lumped element branch line coupler comprises:
a first inductor which is shunt-connected to a first intermediate node located on a first path connecting the first node and the second node;
a second inductor which is shunt-connected to a second intermediate node located on a second path connecting the first node and the third node;
a third inductor which is shunt-connected to a third intermediate node located on a third path connecting the third node and the fourth node; and
a fourth inductor which is shunt-connected to a fourth intermediate node located on a fourth path connecting the second node and the fourth node, and
wherein when the center frequency is fo, a reference impedance is Zo, a first inductance of the first inductor and the third inductor is L1, and a second inductance of the second inductor and the fourth inductor is L2, relationships of L1<Zo/2πfo and L2>L1/√2 are satisfied.

5. The amplifier circuit as claimed in claim 4,
wherein the lumped element branch line coupler comprises:
a pair of first capacitors which are connected on the first path in series where the first intermediate node is therebetween;
a pair of second capacitors which are connected on the second path in series where the second intermediate node is therebetween;
a pair of third capacitors which are connected on the third path in series where the third intermediate node is therebetween; and
a pair of fourth capacitors which are connected on the fourth path in series where the fourth intermediate node is therebetween, and
wherein when a capacitance of each of the pair of first capacitors and the pair of third capacitors is C1, and a capacitance of each of the pair of second capacitors and the pair of fourth capacitors is C2, relationships of C1>1/(2πfo×Zo) and C2<√2/(2πfo×Zo) are satisfied.

6. The amplifier circuit as claimed in claim 2,
wherein the reference impedance is a characteristic impedance of a transmission line provided between the fourth node and an output terminal from which the output signal is output.

7. The amplifier circuit as claimed in claim 1, wherein a difference between a first ratio of an amplitude of an electrical power of the seventh signal to an amplitude of an electrical power of the sixth signal and a second ratio of an amplitude of an electrical power of a signal of the center frequency input to the first node which is distributed to the fourth node to an amplitude of a signal of the center frequency input to the first node which is distributed to the third node is 1 dB or less.

8. The amplifier circuit as claimed in claim 7, wherein the second ratio is 2 dB or more.

9. The amplifier circuit as claimed in claim 1, wherein a saturation electrical power of the first auxiliary amplifier is larger than that of the second auxiliary amplifier.

10. The amplifier circuit as claimed in claim 9,
wherein a ratio of the saturation electrical power of the first auxiliary amplifier to the saturation electrical power of the second auxiliary amplifier is 2 dB or more.

11. The amplifier circuit as claimed in claim 1,
wherein a physical size of the first auxiliary amplifier is larger than that of the second auxiliary amplifier.

12. The amplifier circuit as claimed in claim 1,
wherein an amplitude of an electrical power of the fourth signal is larger than that of the fifth signal.

13. The amplifier circuit as claimed in claim 12,
wherein a ratio of an amplitude of an electrical power of the fourth signal to an amplitude of an electrical power of the fifth signal is 2 dB or more.
